(19) United States
(12) Patent Application Publication
(10) Pub. No.: US 2015/0011077 A1
(43) Pub. Date: Jan. 8, 2015

(54) VAPOR PHASE GROWTH APPARATUS AND VAPOR PHASE GROWTH METHOD

(71) Applicant: NuFlare Technology, Inc., Kanagawa (JP)

(72) Inventors: Takumi YAMADA, Kanagawa (JP); Yuusuke SATO, Tokyo (JP)

(21) Appl. No.: 14/319,546

(22) Filed: Jun. 30, 2014

(30) Foreign Application Priority Data
Jul. 2, 2013 (JP) 2013-139086

(51) Int. Cl. H01L 21/02

(52) U.S. Cl. CPC H01L 21/0262; H01L 21/0254
USPC 438/478; 118/715

(57) ABSTRACT

A vapor phase growth apparatus of an embodiment includes: a reaction chamber configured to perform a film formation process of nitride; a first gas supply path configured to supply a halogen-based gas; a second gas supply path configured to supply an ammonia gas; a shower plate disposed at the upper portion of the reaction chamber, the shower plate configured to supply the halogen-based gas and the ammonia gas into the reaction chamber, the shower plate having a first gas passage and a second gas passage in the shower plate, the first gas passage connected to the first gas supply path and the second gas passage connected to the second gas supply path, the second gas passage being separated from the first gas passage in the shower plate until the second gas passage reaches the reaction chamber; and a substrate provided inside the reaction chamber.

### CROSS-REFERENCE TO RELATED APPLICATION

This application is based upon and claims the benefit of priority from Japanese Patent Application No. 2013-139086, filed on Jul. 2, 2013, the entire contents of which are incorporated herein by reference.

### FIELD OF THE INVENTION

Embodiments described herein relate generally to a vapor phase growth apparatus and a vapor phase growth method of forming a film by supplying a gas thereto.

### BACKGROUND OF THE INVENTION

As a method of forming a high-quality semiconductor film, there is known an epitaxial growth technique of growing a single-crystal film on a substrate such as a wafer by the vapor phase growth. In a vapor phase growth apparatus that uses the epitaxial growth technique, a wafer is placed on a substrate support inside a reaction chamber that is maintained in a normal pressure state or a reduced pressure state. Then, a process gas such as a source gas used as a raw material for forming a film is supplied from, for example, a shower plate (or a shower head) at the upper portion of the reaction chamber to a wafer surface while the wafer is heated. Thus, a thermal reaction of the source gas occurs on the surface of the wafer, and hence an epitaxial single-crystal film is formed on the surface of the wafer.

In recent years, a semiconductor device using GaN (gallium nitride) has been gaining attention as a material of a light emitting device or a power device. As one of the epitaxial growth techniques that forms a GaN-based semiconductor, a metal organic chemical vapor deposition (MOCVD) is known. In the metal organic chemical vapor deposition, for example, a gas including organic metal such as trimethylgallium (TMG), trimethylindium (TMI), and trimethylaluminum (TMA) or an ammonia gas (NH₃) is used as the source gas. Further, there is a case in which a hydrogen gas (H₂) is used as a separation gas in order to suppress the reaction in the source gas.

In the vapor phase growth apparatus that uses the epitaxial growth technique, the inside of the reaction chamber is cleaned after the film formation process. In the cleaning process, for example, a halogen-based gas such as a hydrogen fluoride gas, a chlorine trifluoride gas, a fluorine gas, a hydrochloric gas, or a chlorine gas is used. For example, in the case of MOCVD, when a cleaning gas including halogen flows to a passage supplying an ammonia gas as a source gas of nitrogen, a reaction occurs between the remaining ammonia and the halogen, and hence powdery ammonium halide is produced, thereby causing particles.

JP-A-2003-27240 discloses a vapor phase growth apparatus that includes passages for a source gas and a cleaning gas.

### SUMMARY OF THE INVENTION

According to an aspect, there is provided a vapor phase growth apparatus including: a reaction chamber configured to perform a film formation process of nitride; a first gas supply path configured to supply a halogen-based gas; a second gas supply path configured to supply an ammonia gas; a shower plate disposed at the upper portion of the reaction chamber, the shower plate configured to supply the halogen-based gas and the ammonia gas into the reaction chamber, the shower plate having a first gas passage and a second gas passage in the shower plate, the first gas passage connected to the first gas supply path and the second gas passage connected to the second gas supply path, the second gas passage being separated from the first gas passage in the shower plate until the second gas passage reaches the reaction chamber; and a substrate support provided inside the reaction chamber below the shower plate, the substrate support configured to place a substrate thereon.

According to an aspect, there is provided a vapor phase growth method which is performed by using a vapor phase growth apparatus including: a reaction chamber configured to perform a film formation process of nitride; a first gas supply path configured to supply a halogen-based gas; a second gas supply path configured to supply an ammonia gas; a shower plate disposed at the upper portion of the reaction chamber, the shower plate configured to supply the halogen-based gas and the ammonia gas into the reaction chamber, the shower plate having a first gas passage and a second gas passage in the shower plate, the first gas passage connected to the first gas supply path and the second gas passage connected to the second gas supply path, the second gas passage being separated from the first gas passage in the shower plate until the second gas passage reaches the reaction chamber; and a substrate support provided inside the reaction chamber below the shower plate, the substrate support configured to place a substrate thereon, the vapor phase growth method comprising: carrying in the substrate into the reaction chamber; forming a nitride semiconductor film on the substrate by supplying a gas including organic metal and the ammonia gas supplied from the second gas supply path to the reaction chamber through the shower plate; carrying out the substrate from the reaction chamber; and cleaning the reaction chamber by supplying the halogen-based gas supplied from the first gas supply path to the reaction chamber through the shower plate.

### BRIEF DESCRIPTION OF THE DRAWINGS

FIG. 1 is a schematic cross-sectional view illustrating a vapor phase growth apparatus of a first embodiment;

FIG. 2 is a schematic top view illustrating a shower plate of the first embodiment;

FIG. 3 is a cross-sectional view taken along the line AA of the shower plate of FIG. 2;

FIGS. 4A, 4B, and 4C are cross-sectional views taken along the lines BB, CC, and DD of the shower plate of FIG. 2; and

FIG. 5 is a schematic cross-sectional view illustrating the vapor phase growth apparatus of the second embodiment.

### DETAILED DESCRIPTION OF THE EMBODIMENTS

Hereinafter, embodiments will be described with reference to the drawings.

Furthermore, in the specification, the gravity direction in the state where a vapor phase growth apparatus is provided so as to form a film is defined as the “down”, and the opposite direction is defined as the “up”. Accordingly, the “lower portion” indicates the position of the gravity direction with respect to the reference, and the “downside” indicates the gravity direction with respect to the reference. Then, the “upper portion” indicates the position in the direction opposite to the gravity direction with respect to the reference, and the “upside” indicates the direction opposite to the gravity direction with respect to the reference. Further, the “longitudinal direction” indicates the gravity direction.

Further, in the specification, the “horizontal plane” indicates a plane perpendicular to the gravity direction.

Further, in the specification, the “process gas” generally corresponds to the gas used to form a film on a substrate, and corresponds to, for example, the concept including a source gas, a carrier gas, a separation gas, and the like.

### First Embodiment

A vapor phase growth apparatus of an embodiment includes: a reaction chamber configured to perform a film formation process of nitride; a first gas supply path configured to supply a halogen-based gas; a second gas supply path configured to supply an ammonia gas; a shower plate disposed at the upper portion of the reaction chamber, the shower plate configured to supply the halogen-based gas and the ammonia gas into the reaction chamber, the shower plate having a first gas passage and a second gas passage in the shower plate, the first gas passage connected to the first gas supply path and the second gas passage connected to the second gas supply path, the second gas passage being separated from the first gas passage in the shower plate until the second gas passage reaches the reaction chamber; and a substrate support provided inside the reaction chamber below the shower plate, the substrate support configured to place a substrate thereon.

In particular, the vapor phase growth apparatus of the embodiment additionally includes a third gas supply path. A hydrogen gas or an inert gas is supplied to one of the first gas supply path and the third gas supply path, and a gas including organic metal is supplied to the other of the first gas supply path and the third gas supply path. A second gas supply path configured to supply an ammonia gas. Then the shower plate has a first gas passage, a second gas passage and a third gas passage inside. The first gas passage connected to the first gas supply path, the second gas passage connected to the second gas supply path, and the third gas passage connected to the third gas supply path. The first gas passage includes a plurality of first lateral gas passages disposed within a first horizontal plane and extending in parallel to each other, a plurality of first longitudinal gas passages connected to the first lateral gas passages and extending in a longitudinal direction, and first gas ejection holes at a reaction chamber side of the shower plate. The second gas passage includes a plurality of second lateral gas passages disposed within a second horizontal plane and extending in parallel to each other in the same direction as that of the first lateral gas passages, a plurality of second longitudinal gas passages connected to the second lateral gas passages and extending in the longitudinal direction, and second gas ejection holes at the reaction chamber side of the shower plate. And, the third gas passages includes a plurality of third lateral gas passages disposed within a third horizontal plane and extending in parallel to each other in the same direction as that of the first lateral gas passages, and a plurality of third longitudinal gas passages connected to the third lateral gas passages and extending in the longitudinal direction, and third gas ejection holes at the reaction chamber side of the shower plate. Further, the halogen-based gas is supplied to the first gas supply path or the third gas supply path. In other words, the halogen-based gas is supplied to the gas supply path other than the second gas supply path.

Since the ammonia gas or the halogen-based gas is easily adsorbed to inside of a pipe, a reaction occurs between the halogenated gas and the ammonia gas adsorbed to the pipe even when, after the ammonia gas flows into the same pipe, a purge gas flows thereto, and then the halogenated gas flows thereto. Since the vapor phase growth apparatus of the embodiment has the above-described configuration, the ammonia (NH₃) gas and the halogen-based gas are supplied to the reaction chamber by the different gas passages. Accordingly, it is possible to suppress a problem in which the powdery reactive product produced by the reaction between ammonia and halogen inside the gas passage is introduced as particles into the reaction chamber. Accordingly, it is possible to form a semiconductor film having an excellent film quality.

Hereinafter, a case will be described in which the epitaxial growth of GaN (gallium nitride) is performed by MOCVD (Metal Organic Chemical Vapor Deposition).

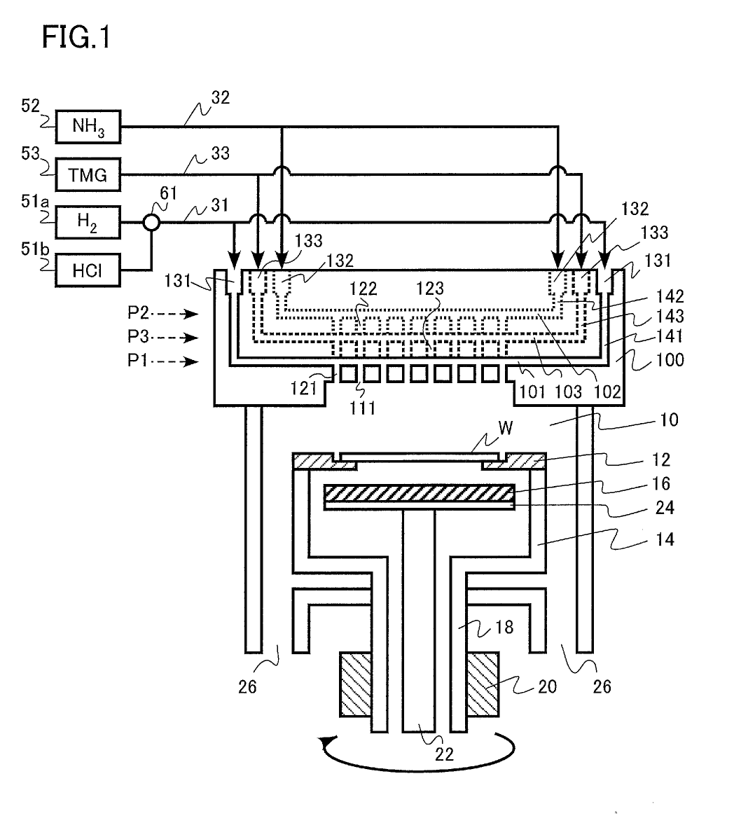

FIG. 1 is a schematic cross-sectional view illustrating the vapor phase growth apparatus of the embodiment. The vapor phase growth apparatus of the embodiment is a single wafer type epitaxial growth apparatus.

As illustrated in FIG. 1, the epitaxial growth apparatus of the embodiment includes a reaction chamber 10 that is formed as, for example, stainless cylindrical hollow body. Then, the epitaxial growth apparatus includes a shower plate 100 that is disposed in the upper portion of the reaction chamber 10 and supplies a process gas into the reaction chamber 10.

Further, the epitaxial growth apparatus of the embodiment includes a substrate support 12 which is provided below the shower plate 100 inside the reaction chamber 10 so as to place a semiconductor wafer (substrate) W thereon. The substrate support 12 is, for example, an annular holder that has an opening formed at the center portion or a susceptor contacting the substantially entire rear surface of the semiconductor wafer W.

Further, a rotation unit 14 which rotates while disposing the substrate support 12 on the upper surface thereof and a heater which serves as a heating unit 16 of heating the wafer W placed on the substrate support 12 are provided below the substrate support 12. Here, a rotation shaft 18 of the rotation unit 14 is connected to a rotational driving mechanism 20 at the lower position thereof. Then, the semiconductor wafer W may be rotated at, for example, 50 rpm to 3000 rpm by the rotational driving mechanism 20 by using the center thereof as the rotation center.

It is desirable that the diameter of the cylindrical rotation unit 14 be substantially equal to the outer peripheral diameter of the substrate support 12. Furthermore, the rotation shaft 18 is rotatably provided at the bottom portion of the reaction chamber 10 through a vacuum seal member.

Then, the heating unit 16 is provided while being fixed onto a support base 24 fixed to a support shaft 22 penetrating the inside of the rotation shaft 18. Electric power is supplied to the heating unit 16 by a current introduction terminal and an electrode (not illustrated). The support base 24 is provided with, for example, a push-up pin (not illustrated) that is used to attach or detach the semiconductor wafer W to or from the annular holder.

Further, the bottom portion of the reaction chamber 10 is provided with a gas discharge portion 26 that discharges a reaction product obtained by the reaction of a source gas on the surface of the semiconductor wafer W and a residual gas of the reaction chamber 10 to the outside of the reaction chamber 10. Furthermore, the gas discharge portion 26 is connected to a vacuum pump (not illustrated).

Then, the epitaxial growth apparatus of the embodiment includes a first gas supply path 31 which supplies a separation gas (a first process gas) of a hydrogen gas or an inert gas, a second gas supply path 32 which supplies an ammonia gas (a second process gas), and a third gas supply path 33 which supplies a gas (a third process gas) including organic metal. Further, the first gas supply path 31 may supply a halogen-based gas.

The first gas supply path 31 is connected to a first gas supply source (A) 51a and a first gas supply source (B) 51b. The first gas supply source (A) 51a becomes a supply source for a hydrogen gas (H₂) or an inert gas as a separation gas.

Here, the separation gas (the first process gas) is a gas which is ejected from first gas ejection holes 111 so as to separate the ammonia gas (the second process gas) ejected from the second gas ejection holes 112 and the gas (the third process gas) including the organic metal ejected from the third gas ejection holes 113. As such a separation gas, a hydrogen gas or an inert gas having insufficient reactivity with respect to the ammonia gas and the gas including organic metal is used. The inert gas is, for example, a helium gas (He), a nitrogen gas (N₂), an argon gas (Ar), or the like.

Further, the first gas supply source (B) 51b becomes a cleaning gas supply source. The cleaning gas is a gas which removes the process gas or the derived material thereof remaining in the reaction chamber or the member inside the reaction chamber after the film formation process. As the cleaning gas, a halogen-based gas including halogen is used. The halogen-based gas is, for example, a hydrochloric acid gas (HCl), a chlorine gas (Cl₂), a fluorine gas (F₂), a hydrogen fluoride gas (HF), or the like. The halogen-based gas may be supplied along with the hydrogen gas or the inert gas.

The first gas supply path 31 includes a passage switching valve 61 provided between the shower plate 100 and the first gas supply source (A) 51a and the first gas supply source (B) 51b. The passage switching valve 61 may switch a gas supplied to the reaction chamber 10 between the separation gas and the cleaning gas.

The second gas supply path 32 is connected to a second gas supply source 52. The second gas supply source 52 becomes a supply source for an ammonia gas (NH₃) as a source gas of a nitride semiconductor film. The ammonia gas may be supplied along with the hydrogen gas or the inert gas.

The third gas supply path 33 is connected to a third gas supply source 53. The third gas supply source 53 becomes a supply source for a gas including organic metal as a source gas of a nitride semiconductor film, for example, a gas obtained by diluting organic metal by hydrogen.

The first gas supply source (A) 51a, the first gas supply source (B) 51b, the second gas supply source 52, and the third gas supply source 53 may be, for example, gas lines supplying the respective gases or may be gas cylinders. Further, the third gas supply source 53 which supplies the gas including organic metal may be the combination of a gas line or a gas cylinder for a carrier gas such as hydrogen or nitrogen and a bubbling mechanism which bubbles liquid organic metal by the diluted gas.

For example, in a case where a single-crystal film of GaN is formed on the semiconductor wafer W by MOCVD, for example, hydrogen (H₂) as a separation gas is supplied as the first process gas. Further, ammonia (NH₃) as a source gas of nitrogen (N) is supplied as the second process gas. Further, for example, a gas obtained by diluting trimethylgallium (TMG) as a source gas of Ga (gallium) by a hydrogen gas (H₂) as a carrier gas is supplied as the third process gas.

FIG. 1 exemplifies a configuration in which the halogen-based gas is supplied to the first gas supply path 31, but the halogen-based gas may be supplied to the third gas supply path 33.

Furthermore, in the single wafer type epitaxial growth apparatus illustrated in FIG. 1, a wafer exit/entrance and a gate valve (not illustrated) through which the semiconductor wafer is inserted and extracted are provided at the side wall position of the reaction chamber 10. Then, the semiconductor wafer W may be carried by a handling arm between, for example, a load lock chamber (not illustrated) connected to the gate valve and the reaction chamber 10. Here, for example, the handling arm formed of synthetic quart may be inserted into the space between the shower plate 100 and the wafer substrate support 12.

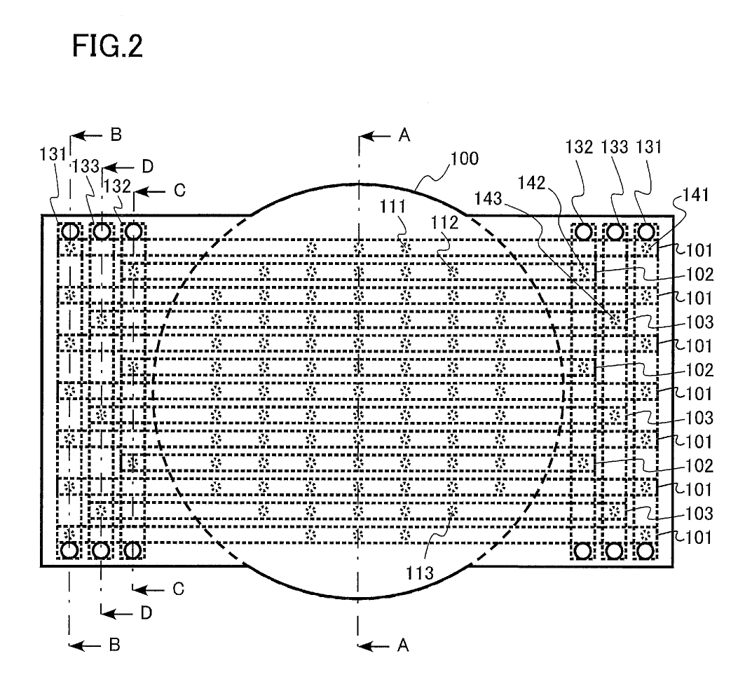

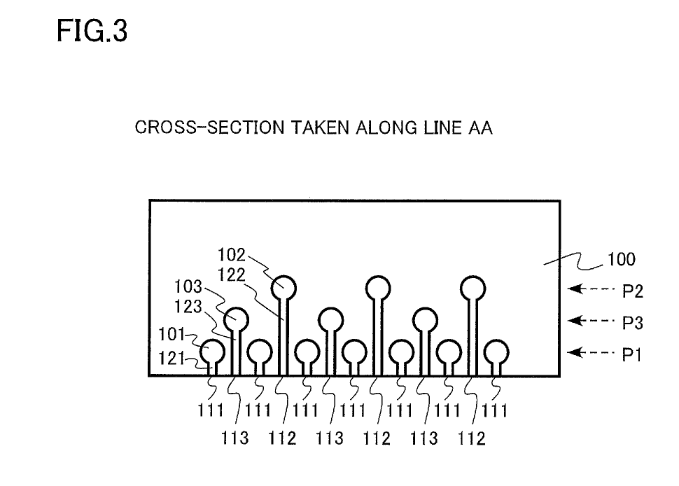

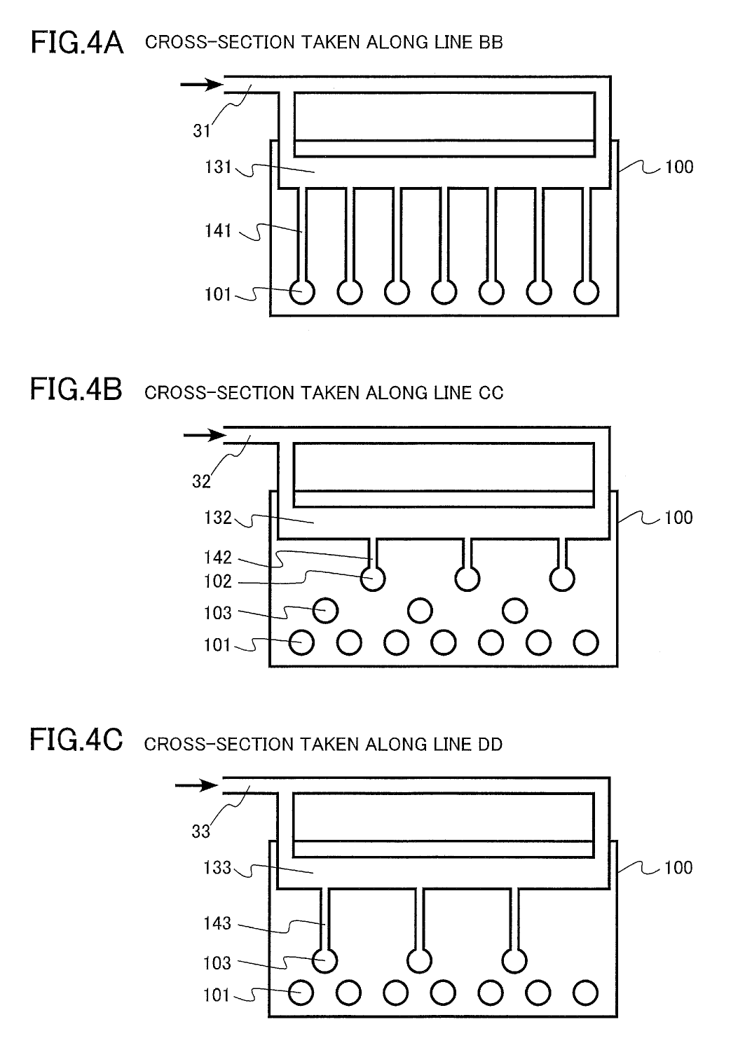

Hereinafter, the shower plate 100 of the embodiment will be described in detail. FIG. 2 is a schematic top view illustrating the shower plate of the embodiment. The structure of the passage or the like inside the shower plate is indicated by the dashed line. FIG. 3 is a cross-sectional view taken along the line AA of FIG. 2, and FIGS. 4A to 4C are cross-sectional views taken along the lines BB, CC, and DD of FIG. 2.

The shower plate 100 has, for example, a plate shape with a predetermined thickness. The shower plate 100 is formed of, for example, a metal material such as stainless steel or aluminum alloy.

A plurality of first lateral gas passages 101, a plurality of second lateral gas passages 102, and a plurality of third lateral gas passages 103 are formed inside the shower plate 100. The plurality of first lateral gas passages 101 extend in parallel to each other within the first horizontal plane (P1). The plurality of second lateral gas passages 102 extend in parallel to each other while being disposed within the second horizontal plane (P2) above the first horizontal plane. The plurality of third lateral gas passages 103 extend in parallel to each other while being disposed within the third horizontal plane (P3) above the first horizontal plane and below the second horizontal plane. The vertical relation of the horizontal plane may not be set in this way. Further, the horizontal planes may be located at the same level.

Then, a plurality of first longitudinal gas passages 121 are provided which are connected to the first lateral gas passages 101 so as to extend in the longitudinal direction and include the first gas ejection holes 111 at the side of the reaction chamber 10. Further, a plurality of second longitudinal gas passages 122 are provided which are connected to the second lateral gas passages 102 so as to extend in the longitudinal direction and include the second gas ejection holes 112 at the side of the reaction chamber 10. The second longitudinal gas passages 122 pass between the first lateral gas passages 101. In addition, a plurality of third longitudinal gas passages 123 are provided which are connected to the third lateral gas passages 103 so as to extend in the longitudinal direction and include third gas ejection holes 113 at the side of the reaction chamber 10. The third longitudinal gas passages 123 pass between the first lateral gas passages 101.

The first lateral gas passages 101, the second lateral gas passages 102, and the third lateral gas passages 103 are lateral holes which are formed inside the plate-shaped shower plate 100 in the horizontal direction. Further, the first longitudinal gas passages 121, the second longitudinal gas passages 122, and the third longitudinal gas passages 123 are longitudinal holes which are formed inside the plate-shaped shower plate 100 in the perpendicular direction (the longitudinal direction or the vertical direction).

The inner diameters of the first, second, and third lateral gas passages 101, 102, and 103 are larger than the inner diameters of the first, second, and third longitudinal gas passages 121, 122, and 123 respectively corresponding thereto. In FIGS. 3 and 4A to 4C, the first, second, and third lateral gas passages 101, 102, and 103 and the first, second, and third longitudinal gas passages 121, 122, and 123 have circular cross-sectional shapes, but the cross-sectional shapes are not limited to the circular shapes. For example, the cross-sectional shapes may be the other shapes such as oval, rectangular, and polygonal shapes.

The shower plate 100 includes a first manifold 131 that is connected to the first gas supply path 31 and is provided above the first horizontal plane (P1) and a first connection passage 141 that connects the first manifold 131 and each first lateral gas passage 101 at the end of the first lateral gas passage 101 and extends in the longitudinal direction.

The first manifold 131 has a function of distributing the first process gas supplied from the first gas supply path 31 to the plurality of first lateral gas passages 101 through the first connection passage 141. The first process gases distributed therefrom are introduced from the first gas ejection holes 111 of the plurality of first longitudinal gas passages 121 into the reaction chamber 10.

The first manifold 131 extends in a direction perpendicular to the first lateral gas passage 101, and has, for example, a hollow parallelepiped shape. In the embodiment, the first manifold 131 is provided in both ends of each first lateral gas passage 101, but may also be provided in at least one end thereof.

Further, the shower plate 100 includes a second manifold 132 that is connected to the second gas supply path 32 and is provided above the first horizontal plane (P1) and a second connection passage 142 that connects the second manifold 132 and each second lateral gas passage 102 at the end of the second lateral gas passage 102 and extends in the longitudinal direction.

The second manifold 132 has a function of distributing the second process gas supplied from the second gas supply path 32 to the plurality of second lateral gas passages 102 through the second connection passage 142. The second process gases distributed therefrom are introduced from the second gas ejection holes 112 of the plurality of second longitudinal gas passages 122 to the reaction chamber 10.

The second manifold 132 extends in a direction perpendicular to the second lateral gas passage 102, and has, for example, a hollow parallelepiped shape. In the embodiment, the second manifold 132 is provided in both ends of the second lateral gas passage 102, but may also be provided in at least one end thereof.

Further, the shower plate 100 includes a third manifold 133 that is connected to the third gas supply path 33 and is provided above the first horizontal plane (P1) and a third connection passage 143 that connects the third manifold 133 and each third lateral gas passage 103 at the end of the third lateral gas passage 103 and extends in the perpendicular direction.

The third manifold 133 has a function of distributing the third process gas supplied from the third gas supply path 33 to the plurality of third lateral gas passages 103 through the third connection passage 143. The third process gases distributed therefrom are introduced from the third gas ejection holes 113 of the plurality of third longitudinal gas passages 123 to the reaction chamber 10.

In general, from the viewpoint of ensuring the uniformity of the formation of the film, it is desirable that the flow amount of the process gas ejected from the gas ejection hole provided as a process gas supply port with respect to the shower plate into the reaction chamber 10 be uniform among the gas ejection holes. According to the shower plate 100 of the embodiment, the process gas is distributed to the plurality of lateral gas passages, is distributed to the longitudinal gas passages, and is ejected from the gas ejection holes. With this configuration, it is possible to improve the uniformity of the flow amount of the process gas ejected from the gas ejection holes by a simple structure.

Further, it is desirable that the arrangement density of the gas ejection holes disposed from the viewpoint of the uniform formation of the film be set as large as possible. More than anything else, in the configuration provided with the plurality of lateral gas passages arranged in parallel to each other as in the embodiment, when the density of the gas ejection holes is increased, a trade-off occurs between the arrangement density of the gas ejection hole and the inner diameter of the lateral gas passage.

For this reason, the fluid resistance of the lateral gas passage increases with a decrease in the inner diameter of the lateral gas passage, and the flow amount distribution of the flow amount of the process gas ejected from the gas ejection hole with respect to the extension direction of the lateral gas passage increases. As a result, there is a concern that the uniformity of the flow amount of the process gas ejected from the respective gas ejection holes may be degraded.

According to the vapor phase growth apparatus of the embodiment, a layered structure is formed in which the first lateral gas passages 101, the second lateral gas passages 102, and the third lateral gas passages 103 are provided in different horizontal planes. With this structure, the margin with respect to an increase in the inner diameter of the lateral gas passage is improved. Accordingly, it is possible to suppress an increase in the flow amount distribution caused by the inner diameter of the lateral gas passage while ensuring the density of the gas ejection holes. As a result, it is possible to improve the uniformity of the formation of the film by equalizing the flow amount distribution of the process gas ejected into the reaction chamber 10.

Further, as described above, the passages of the process gases are separated until the passages reach the reaction chamber 10. Then, the cleaning gases of the ammonia gas (NH₃) and the halogen-based gas are supplied to the reaction chamber by different gas passages. Accordingly, it is possible to suppress a problem in which the powdery reactive product produced by the reaction between ammonia and halogen inside the gas passage is introduced as particles into the reaction chamber. Accordingly, it is possible to form a semiconductor film having an excellent film quality.

As described above, in a case where a single-crystal film of GaN is formed on the semiconductor wafer W by MOCVD, for example, the hydrogen gas (H₂) which becomes the separation gas is supplied as the first process gas. Further, the ammonia gas (NH₃) which becomes the source gas of the nitrogen (N) is supplied as the second process gas. Further, for example, a gas obtained by diluting trimethylgallium (TMG) as the source gas of Ga (gallium) by the hydrogen gas (H₂) as the carrier gas is supplied as the third process gas.

In this case, the ammonia gas (NH₃) as the second process gas has kinematic viscosity smaller than that of the hydrogen gas (H₂) as the first process gas.

In a case where a film of GaN is formed, the ammonia gas (NH₃) as the second process gas is ejected from the second gas ejection holes 112, and the hydrogen gas (H₂) as the first process gas is ejected from the adjacent first gas ejection holes 111. At this time, since the ejection speed of the ammonia gas having kinematic viscosity smaller than that of the hydrogen becomes faster than the ejection speed of the hydrogen having large kinematic viscosity, the dynamic pressure of the ammonia gas increases. Then, since the hydrogen is drawn, the turbulent flow is generated, and hence there is a concern that the flow of the process gas is degraded.

Here, the following relation is satisfied among the voltage (P₀), the static pressure (P), the fluid velocity (v), and the fluid density (ρ).

P+0.5ρv²=P₀

Here, 0.5 ρv² is the dynamic pressure. A so-called venturi effect is generated in which the dynamic pressure increases and the static pressure (P) decreases with an increase in fluid velocity v. For example, when the flow velocity of the ammonia gas is larger than the flow velocity of the hydrogen gas of the separation gas, the static pressure in the vicinity of the gas ejection hole ejecting the ammonia gas decreases, and hence the turbulent flow drawing the hydrogen gas is easily generated.

For this reason, it is desirable to increase, for example, the inner diameter of the second longitudinal gas passage 122 through which the ammonia gas having small kinematic viscosity and large flow velocity flows and to increase the number of the second longitudinal gas passages by narrowing the gap therebetween. Accordingly, the ejection speed of the ammonia gas having small kinematic viscosity is decreased. Accordingly, a difference in ejection speed between the ammonia gas and the first process gas having large kinematic viscosity, that is, the hydrogen gas decreases, and hence the turbulent flow may be suppressed.

Above all, since the inner diameter of the second longitudinal gas passage 122 is increased and the number of the second longitudinal gas passages is increased by narrowing the gap therebetween, the fluid resistance of the second longitudinal gas passage 122 decreases. For this reason, the gas flow amount distribution of the second lateral gas passage 102 in the extension direction increases, and hence there is a concern that the film formation uniformity may be degraded.

Therefore, since the second lateral gas passage 102 is provided above the first lateral gas passage 101, it is desirable to relatively increase the fluid resistance by setting the length of the second longitudinal gas passage 122 to be longer than that of the first longitudinal gas passage 121. Since the fluid resistance of the second longitudinal gas passage 122 is increased, the gas flow amount distribution of the second lateral gas passage 102 in the extension direction may be equalized.

Further, it is desirable to set the inner diameter of the second lateral gas passage 102 to be larger than the inner diameter of the first lateral gas passage 101. Since the fluid resistance of the second lateral gas passage 102 is decreased by increasing the inner diameter of the second lateral gas passage 102, it is possible to equalize the gas flow amount distribution of the second lateral gas passage 102 in the extension direction.

In a case where the lateral gas passage is formed as a layered structure, the uppermost lateral gas passage may have the largest margin in the inner diameter enlargement. This is because the longitudinal gas passages of the other layers do not pass therebetween.

As described above, in a case where the lateral gas passage is formed as a layered structure having three or more layers, it is desirable to provide the lateral gas passage through which the ammonia gas having small kinematic viscosity flows at the uppermost portion as in the embodiment from the viewpoint of equalizing the gas flow amount distribution.

A case will be described in which the epitaxial growth of GaN is performed by using such a vapor phase growth apparatus.

The vapor phase growth method of the embodiment includes: carrying in the substrate into the reaction chamber; and forming the nitride semiconductor film on the substrate by causing the separation gas of the hydrogen gas or the inert gas to flow through the first gas supply path so that the separation gas is ejected from the first gas ejection holes, causing the ammonia gas to flow through the second gas supply path so that the ammonia gas is ejected from the second gas ejection holes, and causing the gas including organic metal to flow through the third gas supply path so that the gas is ejected from the third gas ejection holes. Then, the vapor phase growth method further including: carrying out the substrate from the reaction chamber; and carrying in a dummy wafer hardly causing a reaction with respect to the halogen-based gas such as SiC or SiO₂. In addition, the vapor phase growth method further including: cleaning the reaction chamber by causing the halogen-based gas to flow through the first or third gas supply path so that the halogen-based gas is ejected from the first or third gas ejection holes. That is, the halogen-based cleaning gas does not flow to the gas passage connected to the second gas supply path. In the cleaning process, it is desirable that the hydrogen gas or the inert gas flow through the gas passage into which the halogen-based gas does not flow.

The carrier gas is supplied to the reaction chamber 10, the vacuum pump (not illustrated) is operated so as to discharge the gas inside the reaction chamber 10 from the gas discharge portion 26, and the semiconductor wafer W is placed on the substrate support 12 inside the reaction chamber 10 while the reaction chamber 10 is controlled at a predetermined pressure. Here, the gate valve (not illustrated) of the wafer exit/entrance of the reaction chamber 10 is opened, and the semiconductor wafer W of the load lock chamber is carried into the reaction chamber 10 by the handling arm. Then, the semiconductor wafer W is placed on the substrate support 12 by using, for example, a push-up pin (not illustrated), the handling arm is returned to the load lock chamber, and the gate valve is closed.

Then, the evacuation is performed by the vacuum pump, and predetermined first to third process gases are ejected from the first to third gas ejection holes 111, 112, and 113 while the rotation unit 14 is rotated at a necessary speed. The first process gas is ejected from the first gas ejection holes 111 into the reaction chamber 10 while passing through the first manifold 131, the first connection passages 141, the first lateral gas passages 101, and the first longitudinal gas passages 121 from the first gas supply path 31. Further, the second process gas is ejected from the second gas ejection holes 112 into the reaction chamber 10 while passing through the second manifold 132, the second connection passages 142, the second lateral gas passages 102, and the second longitudinal gas passages 122 from the second gas supply path 32. Further, the third process gas is ejected from the third gas ejection holes 113 into the reaction chamber 10 while passing through the third manifold 133, the third connection passages 143, the third lateral gas passages 103, and the third longitudinal gas passages 123 from the third gas supply path 33.

The semiconductor wafer W placed on the substrate support 12 is pre-heated to a predetermined temperature by the heating unit 16. Further, the heating output of the heating unit 16 is increased so that the temperature of the semiconductor wafer W increases to the epitaxial growth temperature.

In a case where the growth of GaN is performed on the semiconductor wafer W, for example, the first process gas is the hydrogen gas as the separation gas, the second process gas is the ammonia gas as the source gas of the nitrogen, and the third process gas is the source gas in which TMG as the source gas of gallium is diluted by the hydrogen gas as the carrier gas. While the temperature increases, ammonia and TMG are not supplied to the reaction chamber 10. For example, only the hydrogen gas is supplied from the first to third gas ejection holes 111, 112, and 113 and the center gas ejection holes 110.

At this time, the passage switching valve 61 is controlled so that the hydrogen gas as the separation gas is supplied from the first gas supply source (A) 51a to the first gas supply path 31.

After the temperature of the semiconductor wafer W becomes the growth temperature, the ammonia gas is supplied to the second gas ejection holes 112, and the TMG is supplied to the third gas ejection holes 113. The first to third process gases ejected from the first to third gas ejection holes 111, 112, and 113 are appropriately mixed with each other, and are supplied onto the semiconductor wafer W in a rectified state. Accordingly, for example, a single-crystal film of GaN (gallium nitride) is formed on the surface of the semiconductor wafer W by the epitaxial growth.

Then, in a case where the epitaxial growth ends, the supply of the TMG to the third gas ejection holes 113 is stopped, and the growth of the single-crystal film ends.

After the film is formed, the temperature of the semiconductor wafer W starts to fall. Then, the temperature of the semiconductor wafer W decreases to a predetermined temperature, and the supply of ammonia to the second gas ejection holes 112 is stopped. Here, for example, the rotation of the rotation unit 14 is stopped, and the heating output of the heating unit 16 is returned to the first state so as to decrease the temperature to the pre-heating temperature while the semiconductor wafer W having the single-crystal film formed thereon is placed on the substrate support 12.

Next, after the temperature of the semiconductor wafer W is stabilized at a predetermined temperature, the semiconductor wafer W is attached to or detached from the substrate support 12 by, for example, the push-up pin. Then, the gate valve is opened again, the handling arm is inserted between the shower plate 100 and the substrate support 12, and the semiconductor wafer W is placed thereon. Then, the handling arm that loads the semiconductor wafer W thereon is returned to the load lock chamber.

Next, the dummy wafer that hardly causes a reaction with respect to the halogen-based gas such as SiC or SiO₂ is placed on the substrate support 12 inside the reaction chamber 10. Subsequently, the gate valve is closed, the substrate support 12 is heated, and the cleaning gas is ejected into the reaction chamber 10 after the temperature becomes a predetermined temperature. At this time, the passage switching valve 61 is controlled so that the cleaning gas, for example, the hydrochloric gas (HCl) is supplied from the first gas supply source (B) 51b to the first gas supply path 31. The hydrogen gas is supplied to the second and third gas supply paths 32 and 33.

The cleaning gas is ejected from the first gas ejection holes 111 into the reaction chamber 10 while passing through the first manifold 131, the first connection passages 141, the first lateral gas passages 101, and the first longitudinal gas passages 121 from the first gas supply path 31. Accordingly, the reaction chamber 10 and the member inside the reaction chamber 10, for example, the substrate support 12, the rotation unit 14, and the like are cleaned.

After the cleaning process ends as described above, the temperature of the dummy wafer is decreased and the dummy wafer is carried out. Subsequently, the film formation process is performed on the other semiconductor wafer W according to the same process sequence described above.

In the vapor phase growth method of the embodiment, the cleaning gases of the ammonia (NH₃) gas and the halogen-based gas are supplied to the reaction chamber by the different gas passages. Accordingly, it is possible to suppress a problem in which the powdery reactive product produced by the reaction between ammonia and halogen inside the gas passage is introduced as particles into the reaction chamber. Accordingly, it is possible to form a semiconductor film having an excellent film quality.

### Second Embodiment

The vapor phase growth apparatus of the embodiment is the same as that of the first embodiment except that the first gas supply source (B) is the source gas including silicon and halogen for performing the growth of the silicon film, for example, a chloride silane gas (SiHₓCl_{y} (x and y are positive integers)) including silicon and chlorine. Accordingly, the same description as that of the first embodiment will not be repeated.

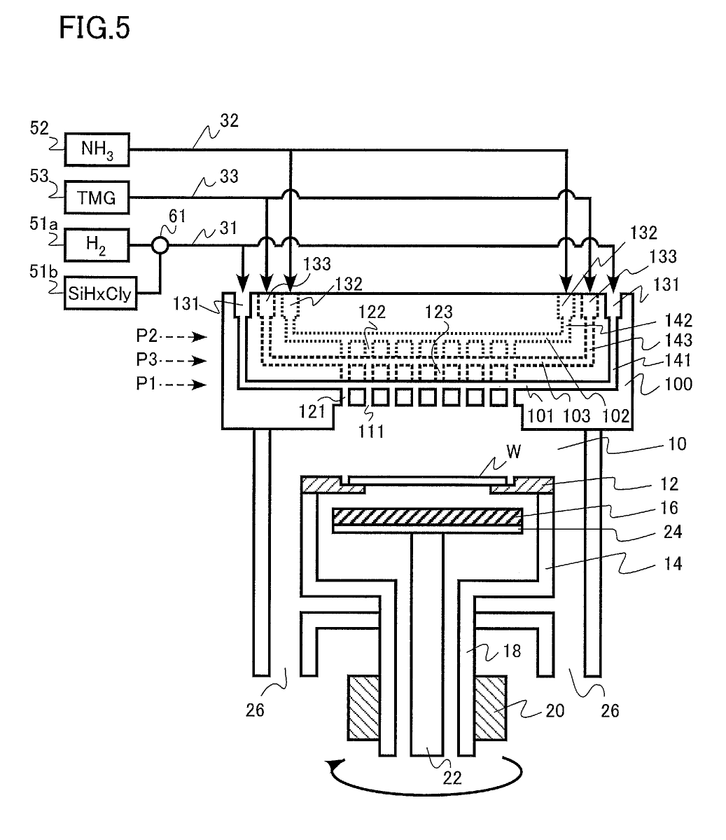

FIG. 5 is a schematic cross-sectional view of the vapor phase growth apparatus of the embodiment. As illustrated in the drawing, the first gas supply source (B) 51b becomes the supply source for the chloride silane gas (SiHₓCl_{y} (x and y are positive integers)). The chloride silane is, for example, dichlorosilane (SiH₂Cl₂) or trichlorosilane (SiHCl₃).

In the embodiment, a silicon film may be formed in addition to the process of forming the nitride semiconductor film. For example, the nitride semiconductor film and the silicon film may be continuously formed without extracting the substrate from the reaction chamber 10.

Then, the ammonia (NH₃) gas used for forming the nitride semiconductor film and the halogen-based gas used for forming the silicon film are supplied to the reaction chamber by different gas passages. Accordingly, it is possible to suppress a problem in which the powdery reactive product produced by the reaction between ammonia and halogen inside the gas passage is introduced as particles into the reaction chamber. Accordingly, it is possible to form a semiconductor film having an excellent film quality.

### Third Embodiment

In the vapor phase growth apparatus of the embodiment, the first to third lateral gas passages are not formed in a layered structure. That is, the third embodiment is the same as the first or second embodiment except that the first to third horizontal planes are the same horizontal plane. Accordingly, the same description as that of the first or second embodiment will not be repeated.

In the embodiments, the structure of the shower plate may be simple in addition to the effect of the first or second embodiment.

As described above, the embodiments have been described with reference to the specific examples. However, the above-described embodiments are merely examples, and do not limit the present disclosure. Further, the components of the embodiments may be appropriately combined with each other. The shower plate does not need to have the above-described structure as long as the ammonia gas and the halogen-based gas pass through different passages inside the shower plate.

For example, in the embodiments, a case has been described in which three kinds of passages such as the lateral gas passage are provided. However, four kinds or more of passages such as the lateral gas passage may be provided or two kinds of passages may be provided.

Further, for example, in the embodiments, a case has been described in which the single-crystal film of gallium nitride (GaN) is formed, but the embodiments may be also applied to, for example, the case of forming a nitride semiconductor such as indium gallium nitride (InGaN), aluminum nitride (AlN), and aluminum gallium nitride (AlGaN) by MOCVD.

Further, the hydrogen gas (H₂) has been exemplified as the process gas having comparatively large kinematic viscosity. However, for example, the helium gas (He) may be exemplified as the process gas having large kinematic viscosity.

Further, in the embodiments, an example of the single wafer type epitaxial apparatus that forms a film for each wafer has been described, but the vapor phase growth apparatus is not limited to the single wafer type epitaxial apparatus. For example, the embodiments may be also applied to a planetary CVD apparatus that simultaneously forms a film on a plurality of wafers that revolve in a spinning state.

In the embodiments, the apparatus configuration or the manufacturing method which is not directly necessary for the description of the invention is not described, but the apparatus configuration or the manufacturing method which needs to be used may be appropriately selected and used. In addition, all vapor phase growth apparatuses and vapor phase growth methods that include the components of the invention and may be appropriately modified in design by the person skilled in the art are included in the scope of the invention. The scope of the invention is defined by the claims and the scope of the equivalent thereof.

What is claimed is:

1. A vapor phase growth apparatus comprising:
a reaction chamber configured to perform a film formation process of nitride;
a first gas supply path configured to supply a halogen-based gas;
a second gas supply path configured to supply an ammonia gas;
a shower plate disposed at the upper portion of the reaction chamber, the shower plate configured to supply the halogen-based gas and the ammonia gas into the reaction chamber, the shower plate having a first gas passage and a second gas passage in the shower plate, the first gas passage connected to the first gas supply path and the second gas passage connected to the second gas supply path, the second gas passage being separated from the first gas passage in the shower plate until the second gas passage reaches the reaction chamber; and
a substrate support provided inside the reaction chamber below the shower plate, the substrate support configured to place a substrate thereon.

2. The vapor phase growth apparatus according to claim 1, further comprising:
a third gas supply path,
wherein a hydrogen gas or an inert gas is supplied to one of the first gas supply path and the third gas supply path,
wherein a gas including organic metal is supplied to the other of the first gas supply path and the third gas supply path,
wherein the shower plate has a third gas passage being connected to the third gas supply path, and third gas passage is separated from the first gas passage and the second gas passage in the shower plate until the third gas passage reaches the reaction chamber,
wherein the first gas passage includes a plurality of first lateral gas passages disposed within a first horizontal plane and extending in parallel to each other, a plurality of first longitudinal gas passages connected to the first lateral gas passages and extending in a longitudinal direction, and first gas ejection holes at a reaction chamber side of the shower plate,
wherein the second gas passage includes a plurality of second lateral gas passages disposed within a second horizontal plane and extending in parallel to each other in the same direction as that of the first lateral gas passages, a plurality of second longitudinal gas passages connected to the second lateral gas passages and extending in the longitudinal direction, and second gas ejection holes at the reaction chamber side of the shower plate,
wherein the third gas passages includes a plurality of third lateral gas passages disposed within a third horizontal plane and extending in parallel to each other in the same direction as that of the first lateral gas passages, and a plurality of third longitudinal gas passages connected to the third lateral gas passages and extending in the longitudinal direction, and third gas ejection holes at the reaction chamber side of the shower plate, and
wherein the halogen-based gas is a cleaning gas including chlorine.

3. The vapor phase growth apparatus according to claim 2,
wherein the second and third horizontal planes are located above the first horizontal plane, and the second and third longitudinal gas passages extend in the longitudinal direction while passing between the first lateral gas passages.

4. The vapor phase growth apparatus according to claim 1,
wherein the halogen-based gas is a cleaning gas including chlorine.

5. The vapor phase growth apparatus according to claim 1,
wherein a hydrogen gas or an inert gas is supplied to the first gas supply path.

6. The vapor phase growth apparatus according to claim 1,
wherein the halogen-based gas is a gas including silicon and chlorine.

7. The vapor phase growth apparatus according to claim 2,
wherein the organic metal is trimethylgallium (TMG).

8. The vapor phase growth apparatus according to claim 1,
wherein the halogen-based gas is a hydrochloric acid gas (HCl) or a chlorine gas (Cl₂).

9. The vapor phase growth apparatus according to claim 2,
wherein the halogen-based gas is a hydrochloric acid gas (HCl) or a chlorine gas (Cl₂).

10. A vapor phase growth method performed by using a vapor phase growth apparatus including: a reaction chamber configured to perform a film formation process of nitride; a first gas supply path configured to supply a halogen-based gas; a second gas supply path configured to supply an ammonia gas; a shower plate disposed at the upper portion of the reaction chamber, the shower plate configured to supply the halogen-based gas and the ammonia gas into the reaction chamber, the shower plate having a first gas passage and a second gas passage in the shower plate, the first gas passage connected to the first gas supply path and the second gas passage connected to the second gas supply path, the second gas passage being separated from the first gas passage in the shower plate until the second gas passage reaches the reaction chamber; and a substrate support provided inside the reaction chamber below the shower plate, the substrate support configured to place a substrate thereon, the vapor phase growth method comprising:
carrying in the substrate into the reaction chamber;
forming a nitride semiconductor film on the substrate by supplying a gas including organic metal and the ammonia gas supplied from the second gas supply path to the reaction chamber through the shower plate;
carrying out the substrate from the reaction chamber; and
cleaning the reaction chamber by supplying the halogen-based gas supplied from the first gas supply path to the reaction chamber through the shower plate.

11. The vapor phase growth method according to claim 10,
wherein the vapor phase growth apparatus further includes a third gas supply path,
wherein the shower plate has a third gas passage being connected to the third gas supply path, and third gas passage is separated from the first gas passage and second gas passage in the shower plate until the third gas passage reaches the reaction chamber,
wherein the shower plate has a third gas passage being connected to the third gas supply path, and third gas passage is separated from the first gas passage and the second gas passage in the shower plate until the third gas passage reaches the reaction chamber,
wherein the first gas passage includes a plurality of first lateral gas passages disposed within a first horizontal plane and extending in parallel to each other, a plurality of first longitudinal gas passages connected to the first lateral gas passages and extending in a longitudinal direction, and first gas ejection holes at a reaction chamber side of the shower plate,
wherein the second gas passage includes a plurality of second lateral gas passages disposed within a second horizontal plane and extending in parallel to each other in the same direction as that of the first lateral gas passages, a plurality of second longitudinal gas passages connected to the second lateral gas passages and extending in the longitudinal direction, and second gas ejection holes at the reaction chamber side of the shower plate,
wherein the third gas passages includes a plurality of third lateral gas passages disposed within a third horizontal plane and extending in parallel to each other in the same direction as that of the first lateral gas passages, and a plurality of third longitudinal gas passages connected to the third lateral gas passages and extending in the longitudinal direction, and third gas ejection holes at the reaction chamber side of the shower plate,
wherein in a case where the nitride semiconductor film is formed, a hydrogen gas or an inert gas flows to one of the first gas supply path and the third gas supply path so as to be ejected from the first or third gas ejection hole, an ammonia gas flows to the second gas supply path so as to be ejected from the second gas ejection hole, and a gas including organic metal flows to the other of the first gas supply path and the third gas supply path so as to be ejected from the first or third gas ejection hole,
wherein in a case where the reaction chamber is cleaned, the halogen-based gas supplied from the first gas supply path is ejected from the first gas ejection hole, and
wherein the halogen-based gas is a cleaning gas including chlorine.

12. The vapor phase growth method according to claim 10,
wherein the halogen-based gas includes chlorine.

13. The vapor phase growth method according to claim 10,
wherein the organic metal is trimethylgallium (TMG).

14. The vapor phase growth method according to claim 11,
wherein the organic metal is trimethylgallium (TMG).

15. The vapor phase growth method according to claim 10,
wherein the halogen-based gas is a hydrochloric acid gas (HCl) or a chlorine gas (Cl₂).

16. The vapor phase growth method according to claim 11,
wherein the halogen-based gas is a hydrochloric acid gas (HCl) or a chlorine gas (Cl₂).
